(19) United States
(12) Patent Application Publication
(10) Pub. No.: US 2022/0223608 A1
(43) Pub. Date: Jul. 14, 2022

(54) BILAYER DIELECTRIC STACK FOR A FERROELECTRIC TUNNEL JUNCTION AND METHOD OF FORMING

(71) Applicant: Tokyo Electron Limited, Tokyo (JP)

(72) Inventors: Steven Consiglio, Albany, NY (US); Kandabara Tapily, Albany, NY (US); Robert Clark, Fremont, CA (US); Dina Triyoso, Albany, NY (US)

(21) Appl. No.: 17/706,958

(22) Filed: Mar. 29, 2022

Related U.S. Application Data
(63) Continuation-in-part of application No. 17/390,399, filed on Jul. 30, 2021.
(60) Provisional application No. 63/063,840, filed on Aug. 10, 2020.

(51) Int. Cl. H01L 27/1159; H01L 27/11507; H01L 29/51; H01L 45/00

(52) U.S. Cl. CPC H01L 27/1159; H01L 45/1616; H01L 29/516; H01L 27/11507

(57) ABSTRACT

Bilayer stack for a ferroelectric tunnel junction and method of forming. The method includes depositing a first metal oxide film on a substrate by performing a first plurality of cycles of atomic layer deposition, where the first metal oxide film contains hafnium oxide, zirconium oxide, or both hafnium oxide and zirconium oxide, depositing a second metal oxide film on the substrate by performing a second plurality of cycles of atomic layer deposition, where the second metal oxide film contains hafnium oxide and zirconium oxide, and has a different hafnium oxide and zirconium oxide content than the first metal oxide film, and heat-treating the substrate to form a ferroelectric phase in the second metal oxide film but not in the first metal oxide film. A ferroelectric tunnel junction includes a first metal-containing electrode, the first metal oxide film, the second metal oxide film, and a second metal-containing electrode.

### CROSS-REFERENCE TO RELATED APPLICATIONS

This application is a continuation-in-part of U.S. patent application Ser. No. 17/390,399, filed Jul. 30, 2021, which claims priority to U.S. Provisional Patent Application No. 63/063,840, filed Aug. 10, 2020; the disclosure of which are expressly incorporated herein, in their entirety, by reference.

### FIELD OF THE INVENTION

The present invention relates to semiconductor processing and semiconductor devices, and more particularly, to substrate processing methods for forming dielectric materials with selected polarization for capacitor devices.

### BACKGROUND OF THE INVENTION

Ferroelectric tunnel junctions (FTJs) are candidate devices for application of artificial synapses in neural networks. FTJs utilize a thin ferroelectric layer sandwiched between two electrodes, which allows electron tunneling through the ferroelectric layer. The two different polarization states are used to alter the potential landscape and therefore change the tunneling transmission coefficient and give the possibility of exhibiting multi-level resistance values through nucleation and propagation of domains of opposed polarity.

### SUMMARY OF THE INVENTION

Embodiments of the invention describe formation of a metal-ferroelectric-dielectric-metal capacitor device that can function as a novel ferroelectric tunnel junction compatible with standard semiconductor fabrication processes. The device includes a bilayer stack with a linear dielectric film and a ferroelectric film, where the device operation can rely on polarization reversal of the ferroelectric film and electron tunneling through the thin linear dielectric film. A relatively thick ferroelectric film can be used in the bilayer stack since the tunneling current is controlled by the thin linear dielectric film.

According to one embodiment, a method of forming a bilayer stack for a ferroelectric tunnel junction includes depositing a first metal oxide film on a substrate by performing a first plurality of cycles of atomic layer deposition, where the first metal oxide film contains hafnium oxide (HfO₂), zirconium oxide (ZrO₂), or both hafnium oxide and zirconium oxide The method further includes depositing a second metal oxide film on the substrate by performing a second plurality of cycles of atomic layer deposition, where the second metal oxide film contains hafnium oxide and zirconium oxide, and has a different hafnium oxide and zirconium oxide content than the first metal oxide film. The method further includes heat-treating the first and second metal oxide films, where a ferroelectric phase is formed in the second metal oxide film but not in the first metal oxide film.

According to one embodiment, a bilayer stack for a ferroelectric tunnel junction includes a first metal oxide film containing hafnium oxide, zirconium oxide, or both hafnium oxide and zirconium oxide, and a second metal oxide film containing hafnium oxide and zirconium oxide, where the second metal oxide film is ferroelectric and the first metal oxide film is a linear dielectric.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 is a flowchart of an example method of manufacturing a bilayer stack according to an embodiment of the invention;

FIGS. 2A-2D show schematic cross-sectional views of an example film structure containing a bilayer stack with a linear dielectric film and a ferroelectric film according to an embodiment of the invention; and

FIG. 3A-3D schematically show gas flow diagrams for depositing metal oxide films according to embodiments of the invention.

### DETAILED DESCRIPTION OF SEVERAL EMBODIMENTS

The present disclosure repeats reference numerals in the various embodiments. This repetition is for the purpose of simplicity and clarity such that repeated reference numerals indicate similar features amongst the various embodiments unless stated otherwise.

Embodiments of the invention describe formation of a metal-ferroelectric-dielectric-metal capacitor device that can find application as a ferroelectric tunnel junction and is compatible with conventional semiconductor fabrication processes. The film structure of the capacitor device includes a bilayer stack containing a first metal oxide film and a second metal oxide film. The first metal oxide film is not ferroelectric but is linearly polarizable, and the second metal oxide film is ferroelectric. According to embodiments of the invention, formation of this film structure is achieved by depositing a bilayer stack of metal oxide films with different HfO₂ content and ZrO₂ content. The combination of the different metal oxide films allows for a thickness of the second metal oxide film to be greater than a thickness of the first metal oxide film. For example, a thickness of the first metal oxide film can be about 1.5 nm, or less.

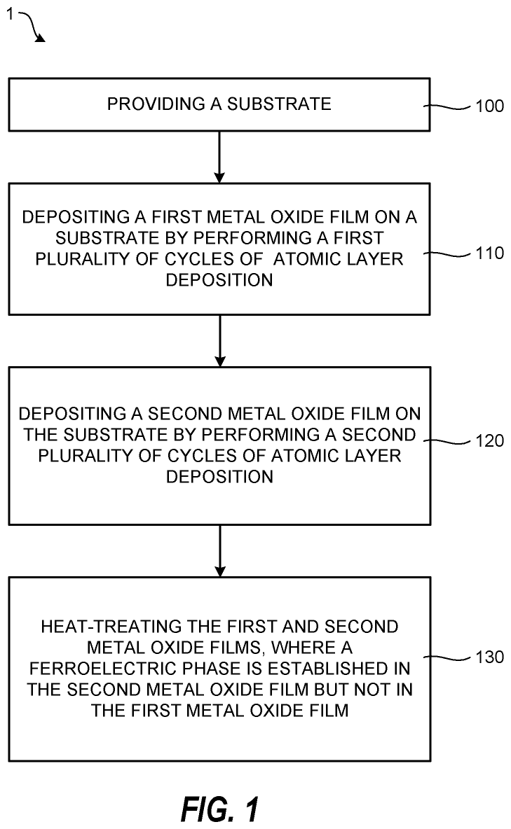

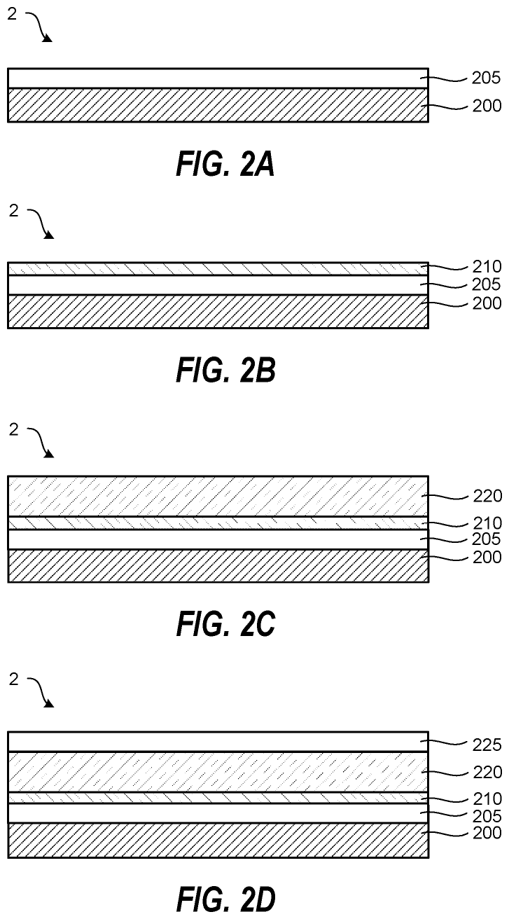

According to one embodiment, schematically shown in FIGS. 1 and 2A-2D, a method in flowchart 1 includes, in 100, providing, in a process chamber, a substrate 2 containing base layer 200 and a first metal-containing electrode layer 205 on the base layer 200. As shown in FIG. 2A, the metal-containing electrode layer 205 may be in direct physical contact with the base layer 200. In one example, the process chamber may be configured to perform atomic layer deposition (ALD) of a dielectric material on the substrate 2. The base layer 200 may, for example, include a semiconductor material, including silicon, germanium, silicon germanium, silicon germanium carbide, gallium arsenic phosphide, gallium indium phosphide, silicon carbide, gallium arsenide, indium arsenide, or indium phosphide. In one example, the base layer 200 may have an epitaxial layer overlying a bulk semiconductor. Furthermore, the base layer 200 may include a semiconductor-on-insulator (SOI) structure. The first metal-containing electrode layer 205 can for example, contain titanium nitride (TiN), tantalum nitride (TaN), or other electrically conductive metal-containing layer and metal layers.

The method further includes, in 110, forming a first metal oxide film 210 on the substrate 2 by performing a first plurality of cycles of ALD. The resulting first metal oxide film 210 has a chemical composition that may be described as mol % HfO₂ and mol % ZrO₂. According to some embodiments, the first metal oxide film 210 may include a laminate of alternating HfO₂ and ZrO₂ layers, or a solid solution of a mixture of HfO₂ and ZrO₂.

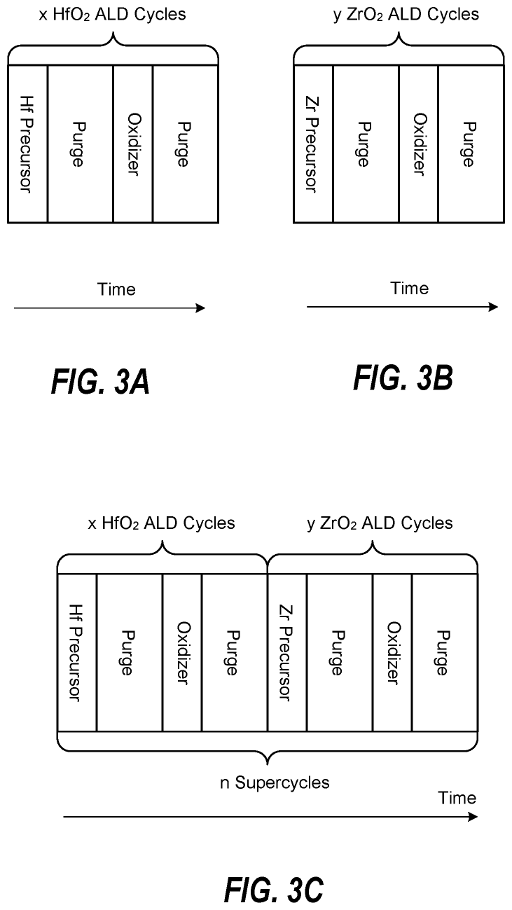

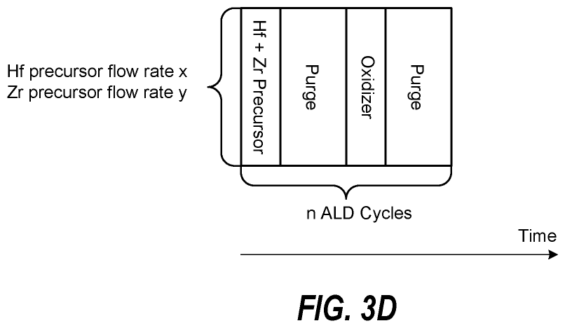

FIG. 3A-3D schematically show gas flow diagrams for depositing metal oxide films according to embodiments of the invention. According to one embodiment, schematically shown in FIG. 3A, the first plurality of cycles of ALD can include x number of cycles of sequential gaseous exposures of a Hf precursor, a purge gas, an oxidizer, and a purge gas to deposit a layer of HfO₂ on the substrate 2. Each exposure of the Hf precursor and the oxidizer can be performed for a time period that results in a saturation exposure on a surface of the substrate 2 and the purge gas exposure removes unreacted reactants and by-products from the process chamber and prevents gas phase mixing of the Hf precursor and the oxidizer. Each cycle deposits one atomic layer or less of HfO₂, and the x number of cycles may be selected in order to accurately control the HfO₂ layer thickness. Steric hindrance of ligands in the Hf precursor and the oxidizer, and a limited number of bonding sites, can limit the chemisorption on the substrate surface, and therefore the HfO₂ film growth per cycle can remain at less than one atomic layer.

According to one embodiment, schematically shown in FIG. 3B, the first plurality of cycles of ALD can include y number of cycles of sequential gaseous exposures of a Zr precursor, a purge gas, an oxidizer, and a purge gas to deposit a layer of ZrO₂ on the substrate 2. Each exposure of the Zr precursor and the oxidizer can be performed for a time period that results in a saturation exposure on a surface of the substrate 2 and the purge gas exposure removes unreacted reactants and by-products from the process chamber and prevents gas phase mixing of the Zr precursor and the oxidizer. Each cycle deposits one atomic layer or less of ZrO₂, and the y number of cycles may be selected in order to accurately control the ZrO₂ layer thickness. Steric hindrance of ligands in the Zr precursor and the oxidizer, and a limited number of bonding sites, can limit the chemisorption on the substrate surface, and therefore the ZrO: film growth per cycle can remain at less than one atomic layer.

According to one embodiment, a hafnium zirconium oxide film may be deposited by sequentially performing x number of HfO₂ ALD cycles and y number of ZrO₂ ALD cycles in a supercycle that may be repeated n times to increase the number of alternating HfO₂ and ZrO₂ layers in the laminate that forms the first metal oxide film 210. The gas flow diagram in FIG. 3C schematically shows the formation of a HfO₂ layer before the formation of a ZrO₂ layer on the HfO₂ layer. However, other embodiments contemplate the formation of a ZrO₂ layer before the formation of a HfO₂ layer on the ZrO₂ layer.

According to another embodiment, schematically shown in FIG. 3D, a hafnium zirconium oxide film may be deposited where the first plurality of cycles of ALD can include n number of cycles of sequential gaseous exposures of a mixture of a Hf precursor and a Zr precursor, a purge gas, an oxidizer, and a purge gas. Each co-exposure of the Hf and Zr precursors and the oxidizer exposure can be performed for a time period that results in a saturation exposure. Each cycle deposits one atomic layer or less of a mixture of HfO₂ and ZrO₂, and the n number of cycles may be selected in order to accurately control the film thickness. The composition of the first metal film 210, which comprises a solid solution of a mixture of HfO₂ and ZrO₂, may be selected by independently controlling the flow rates of the Hf precursor and the Zr precursor that form the mixture that is exposed to the substrate 2.

According to embodiments of the invention, the first metal oxide film 210 is not ferroelectric but is linearly polarizable in the presence of an external electric field. A HfO₂ films and ZrO₂ films are not ferroelectric, and the lack of ferroelectricity in hafnium zirconium oxide films is due to a HfO₂ content or a ZrO₂ content that is below a threshold value needed for ferroelectric phase formation in the first metal oxide film 210 after deposition on the substrate 2 or after a subsequent heat-treating step at an elevated substrate temperature. According to one embodiment, the HfO₂ content or the ZrO₂ content can be less than about 25 mol %. In one example, the HfO₂ content can be between about 10 mol % and about 20 mol %, and balance ZrO₂. In another example, the ZrO₂ content can be between about 10 mol % and about 20 mol %, and balance HfO₂. In another example, the HfO₂ content can be less than about 10 mol %, and balance ZrO₂. In another example, the ZrO₂ content can be less than about 10 mol %, and balance HfO₂.

Following the deposition of the first metal oxide film 210 on the substrate 2, an optional heat-treating process may be performed on the first metal oxide film 210 using a predetermined substrate temperature and time period. The heat-treating may be performed at a substrate temperature between about 400° C. and about 900° C., between about 200° C. and about 500° C., between about 200° C. and about 300° C., between about 300° C. and about 400° C., or between about 400° C. and about 500° C. In one example, the heat-treating may be performed at a substrate temperature of about 500° C., or lower. In one example, the heat-treating may be performed in the same process chamber as the deposition of the first metal oxide film 210. In another example, the heat-treating may be formed in a different process chamber than the deposition of the first metal oxide film 210. The heat-treating may be performed under vacuum conditions in the presence of an inert gas, for example argon (Ar) or nitrogen (N₂).

According to one embodiment, the first metal oxide film 210 may be heat-treated after one or more cycles of the atomic layer deposition, before deposition of the entire first metal oxide film 210. Thus, the heat-treating may be performed before the entire first metal oxide film 210 has been deposited.

The method further includes, in 120, forming a second metal oxide film 220 on the substrate 2 by performing a second plurality of cycles of atomic layer deposition (ALD). The resulting second metal oxide film 220 contains HfO₂ and ZrO₂ and has a chemical composition that may be described as mol % HfO₂ and mol % ZrO₂. According to some embodiments, the second metal oxide film 220 may include a laminate of alternating HfO₂ and ZrO₂ layers, or a solid solution of a mixture of HfO₂ and ZrO₂. The second metal oxide film 220 may be formed as described above for the first metal oxide film 210, including as described in FIGS. 3C and 3D. However, the second metal oxide film 220 has a different chemical composition than the first metal oxide film 210.

According to embodiments of the invention, the second metal oxide film 220 has a HfO₂ content or a ZrO₂ content that is above a threshold value needed for ferrolectric phase formation in the second metal oxide film 220 after deposition on the substrate 2 or after a subsequent heat-treating step at an elevated temperature. Accordingly, the second metal oxide film 220 is ferroelectric. According to one embodiment, the HfO₂ content and the ZrO₂ content are both greater than about 25 mol %. Thus, the HfO₂ content can be greater than about 25 mol %, balance ZrO₂, or the ZrO₂ content can be greater than about 25 mol %, balance HfO₂. Examples include HfO₂ content:ZrO₂ content of about 30 mol %:about 70 mol %, about 40 mol %:about 60 mol %, about 50 mol %:about 50 mol %, about 60 mol %:about 40 mol %, or about 70 mol %:about 30 mol %.

Following the deposition of the second metal oxide film 220 on the substrate 2, a heat-treating process is performed in 130 on the first and second metal oxide films 210, 220 using a predetermined substrate temperature and time period. The heat-treating establishes a ferroelectric phase in the second metal oxide film 220 but the first metal oxide film 210 remains a liner dielectric without a ferroelectric phase. The heat-treating may be performed at a substrate temperature between about 400° C. and about 900° C., between about 200° C. and about 500° C., between about 200° C. and about 300° C., between about 300° C. and about 400° C., or between about 400° C. and about 500° C. In one example, the heat-treating may be performed in the same process chamber as the deposition of the first and second metal oxide films 210, 220. In another example, the heat-treating may be formed in a different process chamber than the deposition of the first and second metal oxide films 210, 220. The heat-treating may be performed under vacuum conditions in the presence of an inert gas, for example argon (Ar) or nitrogen (N2). According to one embodiment, the first metal oxide film 210 is not heat-treated prior to depositing the second metal oxide film 220 on the first metal oxide film 210.

According to embodiments of the invention, the first metal oxide film 210 and the second metal oxide film 220 may be deposited on the substrate 2 in any order. In one example, as schematically shown in FIGS. 2A-2D, the first metal oxide film 210 is deposited with direct contact with the first metal-containing electrode layer 205, and, thereafter the second metal oxide film 220 is deposited with direct physical contact with an upper surface of the first metal oxide film 210. In another example, the second metal oxide film 220 is deposited on the first metal-containing electrode layer 205, and, thereafter the first metal oxide film 210 is deposited with direct physical contact with an upper surface of the second metal oxide film 220.

According to one embodiment, the first metal oxide film 210 and the second metal oxide film 220 differ in HfO₂ content, ZrO₂ content, and film thickness. According to one embodiment, the difference in HfO₂ content, ZrO₂ content, and film thickness is easily achieved by the plurality of cycles of ALD described above and schematically shown in FIGS. 3A-3D. In one example, the x number of HfO₂ ALD cycles and the y number of ZrO₂ ALD cycles in FIG. 3C form a laminate of alternating HfO₂ and ZrO₂ layers, where the number of HfO₂ ALD cycles relative to the number of ZrO₂ ALD cycles may be used to select the chemical composition. In one example, in FIG. 3D, the relative flow rates of a Hf precursor and a Zr precursor in a precursor mixture may be used to achieve the desired chemical composition. Further, the same hafnium precursor, zirconium precursor, oxidizer, and purge gas may be used to deposit both the first metal oxide film 210 and the second metal oxide film 220. This provides several advantages over other methods where different film contain different chemical elements. Some advantages include higher manufacturing throughput, processing in a single process chamber, and fewer different reactants.

In some embodiments, the first metal oxide film 210 may be deposited by any of the gas flow diagram in FIGS. 3A-3D. Similarly, the second metal oxide film 220 may either be deposited by the gas flow diagram in FIG. 3C or by the gas flow diagram in FIG. 3D. In one example, both the first and second metal oxide films 210, 220 may be deposited by the gas flow diagram in FIG. 3C. In another example, both the first and second metal oxide films 210, 220 may be deposited by the gas flow diagram in FIG. 3D. In yet another example, the first metal oxide film 210 may be deposited by the gas flow diagrams in FIG. 3A or 3B and the second metal oxide film 220 may be deposited by the gas flow diagram in FIG. 3C or 3D.

After the heat-treating in 130, a second metal-containing electrode layer 225 may be deposited on the second metal oxide film 220. This is schematically shown in FIG. 2D. The second metal-containing electrode layer 225 can for example, contain titanium nitride (TiN), tantalum nitride (TaN), or other electrically conductive metal-containing layer and metal layers.

Embodiments of the invention may utilize a wide variety of zirconium (Zr) and hafnium (Hf) precursors for the vapor phase deposition. For example, representative examples include: Zr(O^{t}Bu)₄ (zirconium tert-butoxide, ZTB), Zr(NEt₂)₄ (tetrakis(diethylamido)zirconium, TDEAZ), Zr(NMeEt)₄ (tetrakis(ethylmethylamido)zirconium, TEMAZ), Zr(NMe₂)₄ (tetrakis(dimethylamido)zirconium, TDMAZ), Hf(O^{t}Bu)₄ (hafnium tert-butoxide, HTB), Hf(NEt₂)₄ (tetrakis(diethylamido)hafnium, TDEAH), Hf(NEtMe)₄ (tetrakis(ethylmethylamido)hafnium, TEMAH), and Hf(NMe₂)₄ (tetrakis(dimethylamido)hafnium, TDMAH). In some examples, tris(dimethylaminocyclopentadienylhafnium (HfCp(NMe₂)₃) available from Air Liquide as HyALD™ may be used as a hafnium precursor and tris(dimethylaminocyclopentadienylzirconinum (ZrCp(NMe₂)₃) available from Air Liquide as ZyALD™ may be used as a zirconium precursor. The oxidizer may include an oxygen-containing gas, including plasma-excited O₂, water (H₂O), or ozone (O₃).

According to one embodiment, a bilayer stack of the first metal oxide film 210 and the second metal oxide film 220 may be used in a metal-ferroelectric-dielectric-metal capacitor device as schematically shown in FIG. 2D. The bilayer stack includes the relatively thick ferroelectric layer of the second metal oxide film 220 and the thinner linear dielectric layer of the first metal oxide film 210 that controls the tunneling current of the device.

A plurality of embodiments for forming a metal-ferroelectric-dielectric-metal capacitor device that can find application as a ferroelectric tunnel junction and is compatible with conventional semiconductor fabrication processes have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a bilayer stack for a ferroelectric tunnel junction, the method comprising:
depositing a first metal oxide film on a substrate by performing a first plurality of cycles of atomic layer deposition, wherein the first metal oxide film contains hafnium oxide, zirconium oxide, or both hafnium oxide and zirconium oxide;
depositing a second metal oxide film on the substrate by performing a second plurality of cycles of atomic layer deposition, wherein the second metal oxide film contains hafnium oxide and zirconium oxide, and has a different hafnium oxide and zirconium oxide content than the first metal oxide film; and
heat-treating the substrate to form a ferroelectric phase in the second metal oxide film but not in the first metal oxide film.

2. The method of claim 1, wherein the hafnium oxide content or the zirconium oxide content in the first metal oxide film containing both hafnium oxide and zirconium oxide is below a threshold value needed for formation of the ferroelectric phase by the heat-treating.

3. The method of claim 1, wherein the zirconium oxide content or the hafnium oxide content in the first metal oxide film containing both hafnium oxide and zirconium oxide is below about 25 mol %.

4. The method of claim 1, wherein the hafnium oxide content and the zirconium oxide content in the second metal oxide film is greater than about 25 mol %.

5. The method of claim 1, wherein the first metal oxide film exhibits linear polarization in the presence of an external electric field.

6. The method of claim 1, wherein a thickness of the second hafnium oxide film is greater than a thickness of the first metal oxide film.

7. The method of claim 1, wherein a thickness of the first metal oxide film is about 1.5 nm, or less.

8. The method of claim 1, wherein the depositing the first metal oxide film further includes heat-treating the substrate after one or more cycles of the atomic layer deposition.

9. The method of claim 1, wherein the depositing the first metal oxide film containing both hafnium oxide and zirconium oxide or depositing the second metal oxide film includes:
a) sequentially first, exposing the substrate to a hafnium precursor and, sequentially second, exposing the substrate to a purge gas;
b) sequentially first, exposing the substrate to an oxidizer and, sequentially second, exposing the substrate to the purge gas;
c) sequentially first, exposing the substrate to a zirconium precursor and, sequentially second, exposing the substrate to the purge gas; and
d) sequentially first, exposing the substrate to the oxidizer and, sequentially second, exposing the substrate to the purge gas.

10. The method of claim 9, wherein a) and b) are sequentially performed a first number of times before or after c) and d) are sequentially performed a second number of times.

11. The method of claim 1, wherein the depositing the first metal oxide film containing both hafnium oxide and zirconium oxide or depositing the second metal oxide film includes:
a) sequentially first, simultaneously exposing the substrate to a hafnium precursor and a zirconium precursor and, sequentially second, exposing the substrate to a purge gas; and
b) sequentially first, exposing the substrate to an oxidizer and, sequentially second, exposing the substrate to the purge gas.

12. The method of claim 1, wherein heat-treating is performed at a substrate temperature between about 400° C. and about 900° C. in the presence of an inert gas.

13. A bilayer stack for a ferroelectric tunnel junction, the bilayer stack comprising:
a first metal oxide film containing hafnium oxide, zirconium oxide, or both hafnium oxide and zirconium oxide; and
a second metal oxide film containing hafnium oxide and zirconium oxide, wherein the second metal oxide film is ferroelectric and the first metal oxide film is a linear dielectric.

14. The bilayer stack of claim 13, wherein the second hafnium zirconium oxide film has a different hafnium oxide content and zirconium oxide content than the first hafnium zirconium oxide film.

15. The bilayer stack of claim 13, wherein the zirconium oxide content or the hafnium oxide content in the first metal oxide film containing both hafnium oxide and zirconium oxide is below a threshold value needed for formation of the ferroelectric phase.

16. The bilayer stack of claim 13, wherein a thickness of the second metal oxide film is greater than a thickness of the first metal oxide film.

17. The bilayer stack of claim 13, wherein a thickness of the first metal oxide film is about 1.5 nm, or less.

18. A ferroelectric tunnel junction comprising:
a first metal-containing electrode;
a first metal oxide film containing hafnium oxide, zirconium oxide, or both hafnium oxide and zirconium oxide;
a second metal oxide film containing hafnium oxide and zirconium oxide, wherein the second metal oxide film is ferroelectric and the first metal oxide film is a linear dielectric; and
a second metal-containing electrode.

19. The ferroelectric tunnel junction of claim 18, wherein the zirconium oxide content or the hafnium oxide content in the first metal oxide film containing both hafnium oxide and zirconium oxide is below a threshold value needed for formation of the ferroelectric phase.

20. The ferroelectric tunnel junction of claim 18, wherein the zirconium oxide content or the hafnium oxide content in the first metal oxide film containing both hafnium oxide and zirconium oxide is below about 25 mol %, and the hafnium oxide content and the zirconium oxide content in the second metal oxide film is greater than about 25 mol %.
